(19) United States
(12) Patent Application Publication
(10) Pub. No.: US 2019/0295654 A1
(43) Pub. Date: Sep. 26, 2019

(54) SEMICONDUCTOR MEMORY DEVICE AND METHOD OF OPERATING THE SEMICONDUCTOR MEMORY DEVICE

(71) Applicant: SK hynix Inc., Icheon-si (KR)

(72) Inventors: Hee Youl LEE, Icheon-si (KR); Ji Hyun SEO, Seoul (KR)

(73) Assignee: SK hynix Inc., Icheon-si (KR)

(21) Appl. No.: 16/192,528

(22) Filed: Nov. 15, 2018

(30) Foreign Application Priority Data
Mar. 23, 2018 (KR) 10-2018-0033968

(51) Int. Cl. G11C 16/10; G11C 16/08; G11C 16/26; H01L 27/11573; H01L 27/11582

(52) U.S. Cl. CPC G11C 16/10; G11C 16/08; H01L 27/11582; H01L 27/11573; G11C 16/26

(57) ABSTRACT

A semiconductor memory device may include a memory cell array, a peripheral circuit, and a control logic circuit. The memory cell array may include a plurality of memory cells, each of which is capable of storing a plurality of bits of data. The peripheral circuit may drive the memory cell array. The control logic circuit may control the peripheral circuit to perform a first program operation on target memory cells, among the plurality of memory cells, coupled to a target word line based on first partial data, and then perform a second program operation on the target memory cells based on second partial data received after the first program operation is completed.

### CROSS-REFERENCE TO RELATED APPLICATION

The present application claims priority under 35 U.S.C. § 119(a) to Korean patent application number 10-2018-0033968 filed on Mar. 23, 2018, in the Korean Intellectual Property Office, the entire disclosure of which is incorporated herein by reference.

### BACKGROUND

### 1. Technical Field

Various embodiments of the present disclosure generally relate to an electronic device, and more particularly, to a semiconductor memory device and a method of operating the semiconductor memory device.

### 2. Related Art

Generally, a semiconductor memory device may have a two-dimensional structure, in which strings are horizontally arranged on a semiconductor substrate, or a three-dimensional structure, in which strings are vertically stacked on a semiconductor substrate. A three-dimensional memory device may be implemented to overcome a limitation in the degree of integration of a two-dimensional memory device, and may include a plurality of memory cells which are vertically stacked on a semiconductor substrate.

### SUMMARY

An embodiment of the present disclosure may provide for a semiconductor memory device including a memory cell array, a peripheral circuit, and a control logic circuit. The memory cell array may include a plurality of memory cells, each of which is capable of storing a plurality of bits of data. The peripheral circuit may drive the memory cell array. The control logic circuit may control the peripheral circuit to perform a first program operation on target memory cells, among the plurality of memory cells, coupled to a target word line based on first partial data, and then perform a second program operation on the target memory cells based on second partial data received after the first program operation is completed.

An embodiment of the present disclosure may provide for a method of operating a semiconductor memory device including a plurality of memory cells. The method may include: receiving first partial data; performing a first program operation on selected memory cells of the plurality of memory cells based on the first partial data; receiving second partial data; and performing a second program operation on the selected memory cells, based on the first partial data and the second partial data.

An embodiment of the present disclosure may provide for a method of operating a semiconductor memory device to program N pages of data to a plurality of memory cells coupled to a target word line (N is a natural number of 2 or more). The method includes: receiving first partial data including first to k-th page data (k is a natural number of 1 or more and less than N); performing a first program operation on the plurality of memory cells coupled to the target word line, based on the first partial data; receiving second partial data including (k+1)^{th} to N^{th} page data; and performing a second program operation on the plurality of memory cells coupled to the target word line based on the first partial data and the second partial data.

### BRIEF DESCRIPTION OF THE DRAWINGS

FIG. 1 shows a block diagram illustrating a storage device including a semiconductor memory device, in accordance with an embodiment of the present disclosure.

FIG. 2 shows a block diagram illustrating a semiconductor memory device, in accordance with an embodiment of the present disclosure.

FIG. 3 shows a diagram illustrating an embodiment of a memory cell array shown in FIG. 2.

FIG. 4 shows a circuit diagram illustrating a memory block of FIG. 3, in accordance with an embodiment of the present disclosure.

FIG. 5 shows a circuit diagram illustrating a memory block of FIG. 3, in accordance with an embodiment of the present disclosure.

FIG. 6 shows a circuit diagram illustrating a memory block included in a memory cell array of FIG. 2, in accordance with an embodiment of the present disclosure.

FIG. 7 shows a flowchart illustrating a method of operating a semiconductor memory device, in accordance with an embodiment of the present disclosure.

FIG. 8 shows a flowchart illustrating a second program step of FIG. 7.

FIG. 9 shows a diagram illustrating first partial data and second partial data, in accordance with an embodiment of the present disclosure.

FIGS. 10, 11, and 12 show block diagrams for explaining the method of operating the semiconductor memory device, in accordance with the embodiment of FIG. 8.

FIGS. 13 and 14 show diagrams illustrating threshold voltage distributions of memory cells as the results of a first program operation and a second program operation, in accordance with an embodiment of the present disclosure.

FIG. 15 shows a flowchart illustrating a second program operation of FIG. 7.

FIG. 16 shows a block diagram for explaining the method of operating the semiconductor memory device, in accordance with the embodiment of FIG. 15.

FIG. 17 shows a flowchart illustrating a method of operating a semiconductor memory device, in accordance with an embodiment of the present disclosure.

FIG. 18 shows a diagram illustrating first and second partial data, in accordance with an embodiment of the present disclosure.

FIGS. 19 and 20 show diagrams illustrating threshold voltage distributions of memory cells as the results of a first program operation and a second program operation, in accordance with an embodiment of the present disclosure.

FIG. 21 shows a diagram illustrating first and second partial data in data formed of N pages, in accordance with an embodiment of the present disclosure.

FIG. 22 shows a block diagram illustrating an example of the memory controller shown in FIG. 1.

FIG. 23 shows a block diagram illustrating an application example of the storage device of FIG. 1.

FIG. 24 shows a block diagram illustrating a computing system including the storage device of FIG. 23.

### DETAILED DESCRIPTION

A limited number of example embodiments are described below with reference to the accompanying drawings. Additional embodiments consistent with the present teachings are also possible. Therefore, presented embodiments should not be construed as being limiting. The presented embodiments are provided to convey an understanding of the present teachings to those skilled in the art.

In the figures, dimensions may be exaggerated for clarity of illustration. It will be understood that when an element is referred to as being “between” two elements, it can be the only element between the two elements, or one or more intervening elements may also be present.

Hereinafter, embodiments are described with reference to the accompanying drawings. Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as being limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as “first” and “second” may be used to describe various components, but they should not limit the various components. The terms are only used for the purpose of differentiating components from one another. For example, a first component may be referred to as a second component, and a second component may be referred to as a first component, and so forth, without departing from the spirit and scope of the present disclosure. Furthermore, “and/or” may include any one of or a combination of the components indicated.

A singular form may include a plural from as long as the specification does not explicitly indicate the contrary. Furthermore, “include/comprise” or “including/comprising” used in the specification represents that one or more components, steps, operations, and elements exist or are added.

Unless defined otherwise, all terms used in this specification, including technical and scientific terms, have the same meanings as would be generally be understood by those skilled in the related art. The terms defined in generally used dictionaries should be construed as having the same meanings as would be construed in the context of the related art, and unless clearly defined otherwise in this specification, should not be construed as having idealistic or overly formal meanings.

It is also noted that in this specification, “connected/coupled” refers to one component not only directly coupling to another component but also indirectly coupling to another component through one or more intermediate components. On the other hand, “directly connected/directly coupled” refers to one component being in direct contact with another component without an intermediate component.

Various embodiments of the present disclosure are directed to a semiconductor memory device having enhanced operational performance. Additionally, various embodiments of the present disclosure are directed to a method of operating a semiconductor memory device having enhanced operational performance.

In an embodiment, the first partial data may include first page data, second page data, and third page data. In this case, after the first program operation is completed, 3-bit data may be stored in each of the memory cells coupled to the target word line.

In an embodiment, the second partial data may include fourth page data. In this case, after the second program operation is completed, 4-bit data may be stored in each of the target memory cells coupled to the target word line.

In an embodiment, the first partial data may include first page data and second page data. In this case, after the first program operation is completed, 2-bit data may be stored in each of the target memory cells coupled to the target word line.

In an embodiment, the second partial data may include third page data and fourth page data. In this case, after the second program operation is completed, 4-bit data may be stored in each of the target memory cells coupled to the target word line.

In an embodiment, the second partial data may include third page data. In this case, after the second program operation is completed, 3-bit data may be stored in each of the target memory cells coupled to the target word line.

In an embodiment, the control logic circuit may control the peripheral circuit to read the first partial data stored in the target memory cells coupled to the target word line and then perform the second program operation based on the read first partial data and the received second partial data.

In an embodiment, after the first program operation, the first partial data and the second partial data may be received. In this case, the control logic circuit may control the peripheral circuit to perform the second program operation based on the received first partial data and the received second partial data.

In an embodiment, the peripheral circuit may include a read/write circuit coupled to the memory cell array through a plurality of bit lines. During the first program operation, the first partial data may be loaded on the read/write circuit. During the second program operation, the first partial data and the second partial data may be loaded on the read/write circuit.

In an embodiment, performing the second program operation includes: loading the second partial data on a read/write circuit coupled to the selected memory cells; reading the selected memory cells and loading the first partial data on the read/write circuit; and programming the selected memory cells based on the loaded first and second partial data.

In an embodiment, in receiving the second partial data, the first partial data may be received along with the second partial data. In this case, the performing the second program operation includes: loading the first partial data and the second partial data on a read/write circuit coupled to the selected memory cells; and programming the selected memory cells based on the loaded first partial data and the loaded second partial data.

In an embodiment, performing the second program operation includes: loading the second partial data on a read/write circuit coupled to the selected memory cells; determining whether the first partial data has been received along with the second partial data; loading the first partial data on the read/write circuit based on a result of the determining; and programming the selected memory cells based on the loaded first partial data and the loaded second partial data.

In an embodiment, the loading of the first partial data on the read/write circuit based on the result of the determining may include loading, when the first partial data is received along with the second partial data, the received first partial data on the read/write circuit.

In an embodiment, the loading of the first partial data on the read/write circuit based on the result of the determining may include reading, when the first partial data is not received along with the second partial data, the first partial data from the selected memory cells, and loading the first partial data on the read/write circuit.

In an embodiment, when performing the first program operation is completed, 3-bit data may be stored in each of the selected memory cells.

In an embodiment, when performing the second program operation is completed, 4-bit data may be stored in each of the selected memory cells.

In an embodiment, when performing the first program operation is completed, 2-bit data may be stored in each of the selected memory cells.

In an embodiment, when performing the second program operation is completed, 2-bit data may be stored in each of the selected memory cells.

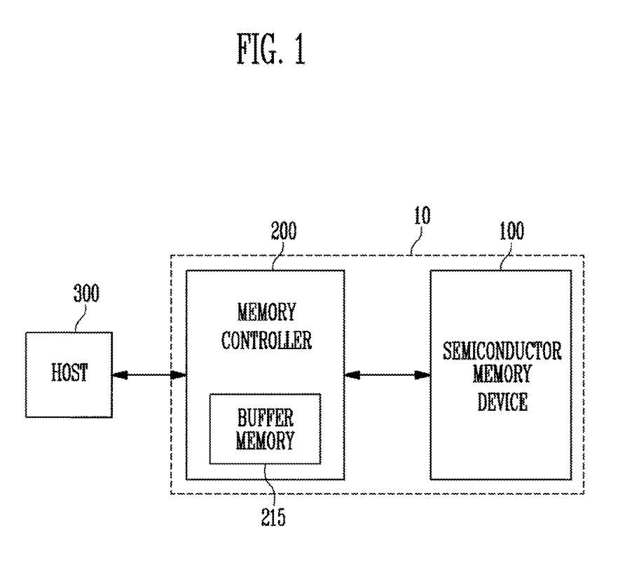

FIG. 1 shows a block diagram illustrating a storage device 10 including a semiconductor memory device 100, in accordance with an embodiment of the present disclosure.

Referring FIG. 1, the storage device 10 includes the semiconductor memory device 100 and a memory controller 200. Furthermore, the storage device 10 may communicate with a host 300. The memory controller 200 may control the overall operation of the semiconductor memory device 100. In addition, the memory controller 200 may control the operation of the semiconductor memory device 100 based on a command received from the host 300.

The memory controller 200 may include a buffer memory 215. The buffer memory 215 may temporarily store program data received from the host 200. The program data temporarily stored in the buffer memory 215 may be transmitted to the semiconductor memory device 100. The semiconductor memory device 100 may perform a program operation based on the received program data. Furthermore, the buffer memory 215 may temporarily store read data received from the semiconductor memory device 100. The semiconductor memory device 100 may perform a read operation under the control of the memory controller 200, and may transmit read data to the memory controller 200 as a result of performing the read operation. The memory controller 200 may temporarily store the received read data in the buffer memory 215 and then transmit the read data to the host 300.

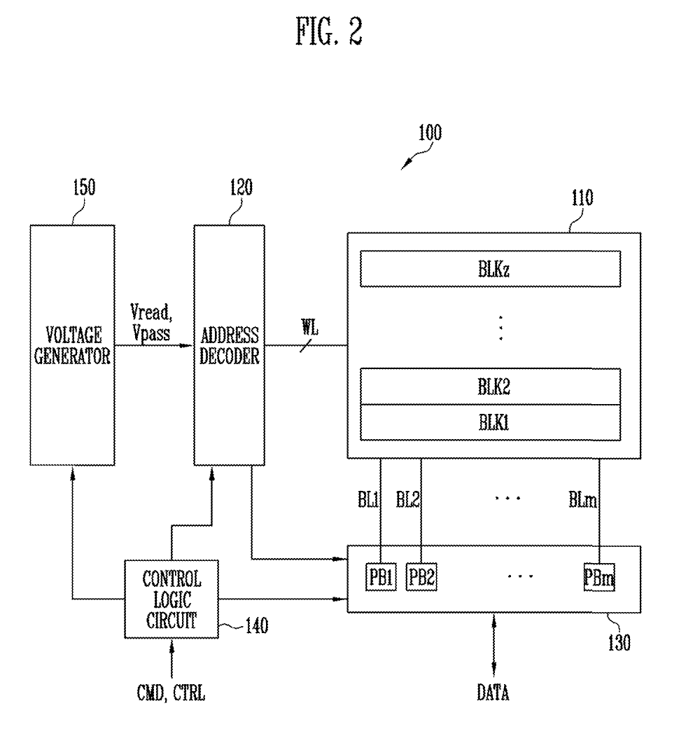

FIG. 2 shows a block diagram illustrating the semiconductor memory device 100, in accordance with an embodiment of the present disclosure.

Referring to FIG. 2, the semiconductor memory device 100 is shown to include a memory cell array 110, an address decoder 120, a read/write circuit 130, a control logic circuit 140, and a voltage generator 150. For some embodiments, a read/write circuit refers to a read and write circuit.

The memory cell array 110 includes a plurality of memory blocks BLK1 to BLKz. The memory blocks BLK1 to BLKz are coupled to the address decoder 120 through word lines WL. The memory blocks BLK1 to BLKz are coupled to the read/write circuit 130 through bit lines BL1 to BLm. Each of the memory blocks BLK1 to BLKz includes a plurality of memory cells. In an embodiment, the memory cells may be nonvolatile memory cells and may be formed of nonvolatile memory cells having a vertical channel structure. For some embodiments, the memory cell array 110 may be formed of a memory cell array having a two-dimensional structure. In other embodiments, the memory cell array 110 may be formed of a memory cell array having a three-dimensional structure. Each of the memory cells included in the memory cell array may store at least one bit of data. In an embodiment, each of the memory cells included in the memory cell array 110 is a single-level cell (SLC), which stores 1-bit data. In an embodiment, each of the memory cells included in the memory cell array 110 is a multi-level cell (MLC), which stores 2-bit data. In an embodiment, each of the memory cells included in the memory cell array 110 is a triple-level cell (TLC), which stores 3-bit data. In an embodiment, each of the memory cells included in the memory cell array 110 is a quad-level cell (QLC), which stores 4-bit data. In various embodiments, the memory cell array 110 may include a plurality of memory cells, each of which stores 5 or more bits of data.

The address decoder 120, the read/write circuit 130, the control logic circuit 140, and the voltage generator 150 are operated as peripheral circuits for driving the memory cell array 110. The address decoder 120 is coupled to the memory cell array 110 through the word lines WL. The address decoder 120 may operate under the control of the control logic circuit 140. The address decoder 120 may receive addresses through an input/output buffer (not shown) provided in the semiconductor memory device 100.

The address decoder 120 may decode a block address among received addresses. The address decoder 120 may select at least one memory block based on the decoded block address. When a read voltage application operation is performed during a read operation, the address decoder 120 may apply a read voltage Vread, generated from the voltage generator 150, to a selected word line of a selected memory block and apply a pass voltage Vpass to the other unselected word lines. During a program verify operation, the address decoder 120 may apply a verify voltage, generated from the voltage generator 150, to a selected word line of a selected memory block and apply a pass voltage Vpass to the other unselected word lines.

The address decoder 120 may decode a column address among the received addresses. The address decoder 120 may transmit the decoded column address to the read/write circuit 130.

For some embodiments, the read or program operation of the semiconductor memory device 100 is performed on a page basis. Addresses received in a request for a read or program operation may include a block address, a row address, and a column address. The address decoder 120 may select one memory block and one word line in response to the block address and the row address. The column address may be decoded by the address decoder 120 and provided to the read/write circuit 130.

The address decoder 120 may include a block decoder, a row decoder, a column decoder, an address buffer, etc.

The read/write circuit 130 includes a plurality of page buffers PB1 to PBm. The read/write circuit 130 may be operated as a read circuit during a read operation of the memory cell array 110 and as a write circuit during a write operation. The page buffers PB1 to PBm are coupled to the memory cell array 110 through the bit lines BL1 to BLm. During a read operation or a program verify operation, to sense threshold voltages of the memory cells, the page buffers PB1 to PBm may continuously supply sensing current to the bit lines coupled to the memory cells, and each page buffer may sense, through a sensing node, a change in the amount of flowing current depending on a program state of a corresponding memory cell and latch it as sensing data. The read/write circuit 130 is operated in response to page buffer control signals outputted from the control logic circuit 140.

During a read operation, the read/write circuit 130 may sense data of the memory cells and temporarily store read-out data, and then output data DATA to the input/output buffer (not shown) of the semiconductor memory device 100. In an embodiment, the read/write circuit 130 may include a column select circuit or the like as well as the page buffers (or page registers).

The control logic circuit 140 is coupled to the address decoder 120, the read/write circuit 130, and the voltage generator 150. The control logic circuit 140 may receive a command CMD and a control signal CTRL through the input/output buffer (not shown) of the semiconductor memory device 100. The control logic circuit 140 may control the overall operation of the semiconductor memory device 100 in response to the control signal CTRL. The control logic circuit 140 may output a control signal for controlling the sensing node precharge potential levels of the plurality of page buffers PB1 to PBm. The control logic circuit 140 may control the read/write circuit 130 to perform a read operation of the memory cell array 110. For some embodiments, the control logic circuit 140 includes a processor.

The voltage generator 150 may generate a read voltage Vread and a pass voltage Vpass during a read operation, in response to a control signal outputted from the control logic circuit 140. The voltage generator 150 may include, so as to generate a plurality of voltages having various voltage levels, a plurality of pumping capacitors configured to receive an internal supply voltage, and may generate a plurality of voltages by selectively enabling the plurality of pumping capacitors under control of the control logic circuit 140.

The address decoder 120, the read/write circuit 130, and the voltage generator 150 may function as peripheral circuits for performing a read operation, a write operation, or an erase operation on the memory cell array 110. The peripheral circuit may perform a read operation, a write operation, or an erase operation on the memory cell array 110 under the control of the control logic circuit 140.

The semiconductor memory device 100 in accordance with an embodiment of the present disclosure may receive first partial data and perform a first program operation on selected memory cells, and thereafter receive second partial data and perform a second program operation on the selected memory cells. Thereby, the operational performance of the semiconductor memory device 100 may be enhanced.

FIG. 3 shows a diagram illustrating an embodiment of the memory cell array 110 of FIG. 2.

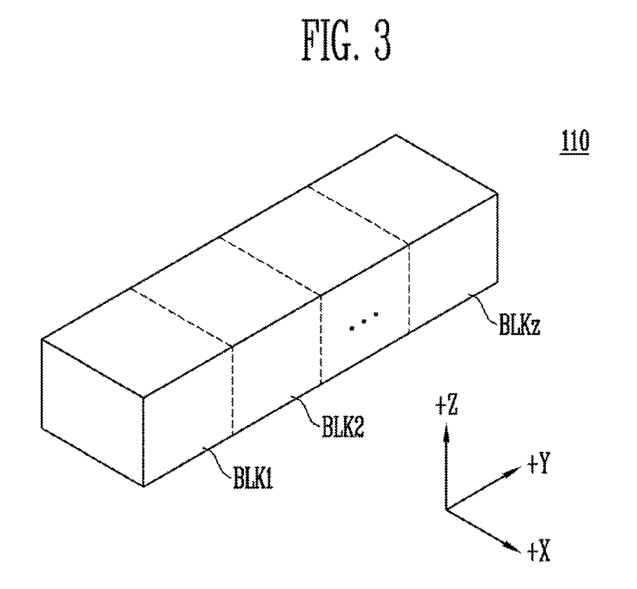

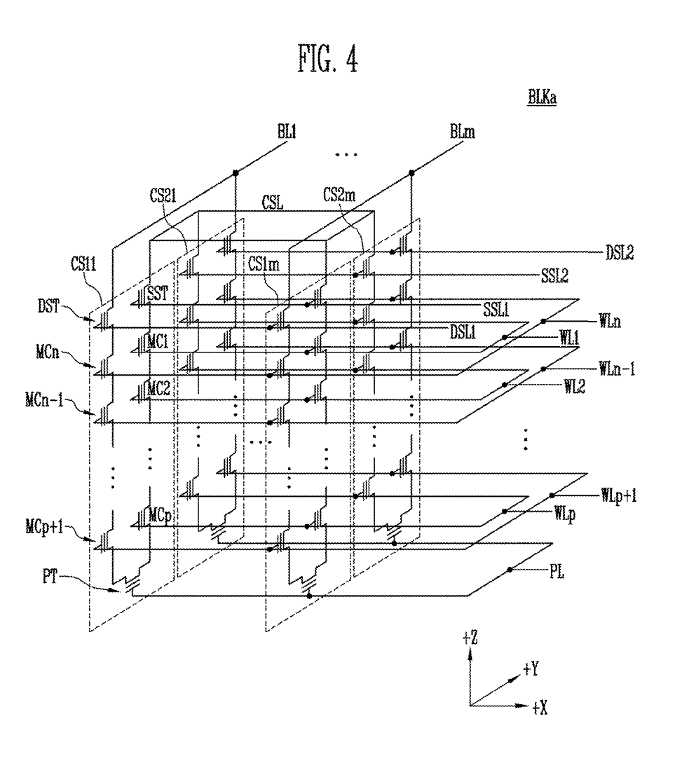

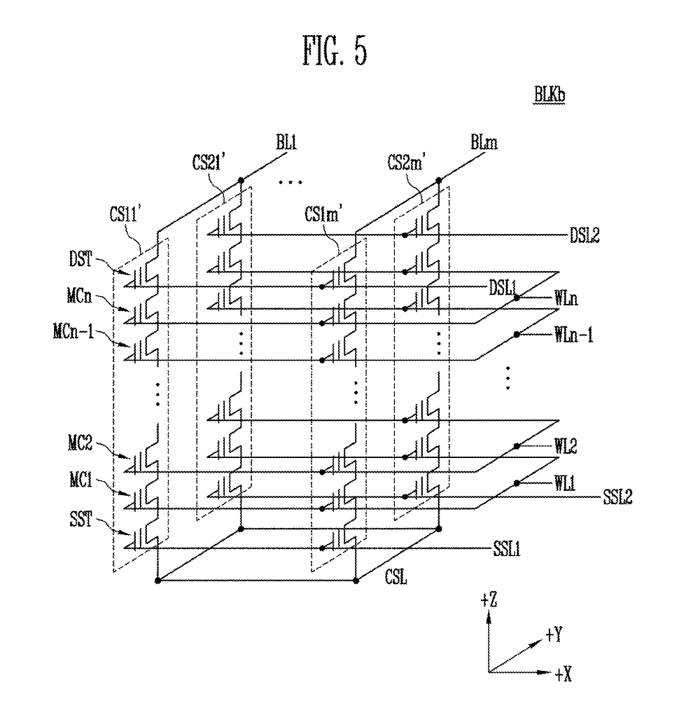

Referring to FIG. 3, the memory cell array 110 may include a plurality of memory blocks BLK1 to BLKz. Each memory block may have a three-dimensional structure. Each memory block may include a plurality of memory cells stacked on a substrate. The memory cells are arranged in a +X direction, a +Y direction, and a +Z direction. The structure of each memory block is described in more detail with reference to FIGS. 4 and 5.

FIG. 4 shows a circuit diagram illustrating any one memory block BLKa of the memory blocks BLK1 to BLKz of FIG. 3, in accordance with an embodiment of the present disclosure.

Referring to FIG. 4, the memory block BLKa may include a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings may be arranged in a row direction (i.e., the +X direction). In FIG. 4, pairs of cell strings are illustrated as being arranged in a column direction (i.e., the +Y direction). However, this illustration is made only for convenience of description, and it will be understood that three or more cell strings may be arranged in the column direction.

Each of the plurality of cell strings CS11 to CS1m and CS21 to CS2m may include at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between the common source line CSL and the memory cells MC1 to MCp.

In an embodiment, source select transistors of cell strings arranged in the same row are coupled to a source select line extending in the row direction, and source select transistors of cell strings arranged in different rows are coupled to different source select lines. In FIG. 4, source select transistors of the cell strings CS11 to CS1m in a first row are coupled to a first source select line SSL1. Source select transistors of the cell strings CS21 to CS2m in a second row are coupled to a second source select line SSL2.

In an embodiment, the source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and p+1-th to n-th memory cells MCp+1 to MCn. The first to p-th memory cells MC1 to MCp are successively arranged in a direction opposite to the +Z direction and are coupled in series between the source select transistor SST and the pipe transistor PT. The p+1-th to n-th memory cells MCp+1 to MCn are successively arranged in the +Z direction and are coupled in series between the pipe transistor PT and the drain select transistor DST. The first to p-th memory cells MC1 to MCp and the p+1-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

Respective gates of the pipe transistors PT of the cell strings are coupled to a pipeline PL.

The drain select transistor DST of each cell string is coupled between the corresponding bit line and the memory cells MCp+1 to MCn. The cell strings arranged in the row direction are coupled to drain select lines extending in the row direction. Drain select transistors of the cell strings CS11 to CS1m in the first row are coupled to a first drain select line DSL1. Drain select transistors of the cell strings CS21 to CS2m in the second row are coupled to a second drain select line DSL2.

Cell strings arranged in the column direction may be coupled to bit lines extending in the column direction. In FIG. 4, cell strings CS11 and CS21 in a first column are coupled to a first bit line BL1. Cell strings CS1m and CS2m in an m-th column are coupled to an m-th bit line BLm.

Memory cells coupled to the same word line in cell strings arranged in the row direction form a single page. For example, memory cells coupled to the first word line WL1, among the cell strings CS11 to CS1m in the first row, form a single page. Memory cells coupled to the first word line WL1, among the cell strings CS21 to CS2m in the second row, form another single page. When any one of the drain select lines DSL1 and DSL2 is selected, corresponding cell strings arranged in the direction of a single row may be selected. When any one of the word lines WL1 to WLn is selected, a corresponding single page may be selected from the selected cell strings.

In an embodiment, even bit lines and odd bit lines may be provided in lieu of the first to m-th bit lines BL1 to BLm. Even-numbered cell strings of the cell strings CS11 to CS1m or CS21 to CS2m arranged in the row direction may be coupled to respective even bit lines. Odd-numbered cell strings of the cell strings CS11 to CS1m or CS21 to CS2m arranged in the row direction may be coupled to respective odd bit lines.

In an embodiment, at least one of the first to n-th memory cells MC1 to MCn may be used as a dummy memory cell. For example, one or more dummy memory cells may be provided to reduce an electric field between the source select transistor SST and the memory cells MC1 to MCp. Alternatively, one or more dummy memory cells may be provided to reduce an electric field between the drain select transistor DST and the memory cells MCp+1 to MCn. As the number of dummy memory cells is increased, the reliability in operation of the memory block BLKa may be increased, while the size of the memory block BLKa may be increased. As the number of dummy memory cells is reduced, the size of the memory block BLKa may be reduced, but the reliability in operation of the memory block BLKa may be reduced.

To efficiently control the one or more dummy memory cells, each of the dummy memory cells may have a required threshold voltage. Before or after an erase operation on the memory block BLKa is performed, program operations may be performed on all or some of the dummy memory cells. In the case where an erase operation is performed after a program operation has been performed, the dummy memory cells may have required threshold voltages by controlling voltages to be applied to the dummy word lines coupled to the respective dummy memory cells.

FIG. 5 shows a circuit diagram illustrating any one memory block BLKb of the memory blocks BLK1 to BLKz of FIG. 3, in accordance with an embodiment of the present disclosure.

Referring to FIG. 5, the memory block BLKb may include a plurality of cell strings CS11′ to CS1m′ and CS21′ to CS2m′. Each of the cell strings CS11′ to CS1m′ and CS21′ to CS2m′ extends in the +Z direction. Each of the cell strings CS11′ to CS1m′ and CS21′ to CS2m′ may include at least one source select transistor SST, first to n-th memory cells MC1 to MCn, and at least one drain select transistor DST, which are stacked on a substrate (not shown) provided in a lower portion of the memory block BLK1′.

The source select transistor SST of each cell string is coupled between the common source line CSL and the memory cells MC1 to MCn. The source select transistors of cell strings arranged in the same row are coupled to the same source select line. Source select transistors of the cell strings CS11′ to CS1m′ arranged in a first row may be coupled to a first source select line SSL1. Source select transistors of the cell strings CS21′ to CS2m′ arranged in a second row may be coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are coupled in series between the source select transistor SST and the drain select transistor DST. Gates of the first to n-th memory cells MC1 to MCn are respectively coupled to first to n-th word lines WL1 to WLn.

The drain select transistor DST of each cell string is coupled between the corresponding bit line and the memory cells MC1 to MCn. Drain select transistors of cell strings arranged in the row direction may be coupled to drain select lines extending in the row direction. Drain select transistors of the cell strings CS11′ to CS1m′ in the first row are coupled to a first drain select line DSL1. Drain select transistors of the cell strings CS21′ to CS2m′ in the second row may be coupled to a second drain select line DSL2.

Consequentially, the memory block BLKb of FIG. 5 may represent an equivalent or similar circuit to that of the memory block BLKa of FIG. 4, except that a pipe transistor PT is excluded from each cell string of the memory block BLKb.

In an embodiment, even bit lines and odd bit lines may be provided in lieu of the first to m-th bit lines BL1 to BLm. Even-numbered cell strings among the cell strings CS11′ to CS1m′ or CS21′ to CS2m′ arranged in the row direction may be coupled to the respective even bit lines, and odd-numbered cell strings among the cell strings CS11′ to CS1m′ or CS21′ to CS2m′ arranged in the row direction may be coupled to the respective odd bit lines.

In an embodiment, at least one of the first to n-th memory cells MC1 to MCn may be used as a dummy memory cell. For example, one or more dummy memory cells may be provided to reduce an electric field between the source select transistor SST and the memory cells MC1 to MCn. Alternatively, one or more dummy memory cells may be provided to reduce an electric field between the drain select transistor DST and the memory cells MC1 to MCn. As the number of dummy memory cells is increased, the reliability in operation of the memory block BLKb may be increased, while the size of the memory block BLKb may be increased. As the number of dummy memory cells is reduced, the size of the memory block BLKb may be reduced, but the reliability in operation of the memory block BLKb may be reduced.

To efficiently control the one or more dummy memory cells, each of the dummy memory cells may have a required threshold voltage. Before or after an erase operation on the memory block BLKb is performed, program operations may be performed on all or some of the dummy memory cells. In the case where an erase operation is performed after a program operation has been performed, the dummy memory cells may have required threshold voltages by controlling voltages to be applied to the dummy word lines coupled to the respective dummy memory cells.

FIG. 6 shows a circuit diagram illustrating any one memory block BLKc of the memory blocks BLK1 to BLKz included in the memory cell array 110 of FIG. 2, in accordance with an embodiment of the present disclosure.

Referring to FIG. 6, the memory block BLKc includes a plurality of cell strings CS1 to CSm. The plurality of cell strings CS1 to CSm may be respectively coupled to a plurality of bit lines BL1 to BLm. Each of the cell strings CS1 to CSm includes at least one source select transistor SST, first to n-th memory cells MC1 to MCn, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between the common source line CSL and the memory cells MC1 to MCn.

The first to n-th memory cells MC1 to MCn in each cell string are coupled between the source select transistor SST and the drain select transistor DST.

The drain select transistor DST of each cell string is coupled between the corresponding bit line and the memory cells MC1 to MCn.

Memory cells coupled to the same word line may form a single page. The cell strings CS1 to CSm may be selected by selecting the drain select line DSL. When any one of the word lines WL1 to WLn is selected, a corresponding single page may be selected from the selected cell strings.

In an embodiment, even bit lines and odd bit lines may be provided in lieu of the first to m-th bit lines BL1 to BLm. Even-numbered cell strings of the cell strings CS1 to CSm may be coupled to the respective even bit lines, and odd-numbered cell strings may be coupled to the respective odd bit lines.

FIG. 7 shows a flowchart illustrating a method of operating a semiconductor memory device, in accordance with an embodiment of the present disclosure.

Referring to FIG. 7, the method of operating the semiconductor memory device includes receiving S110 first partial data, performing S130 a first program operation on selected memory cells of the plurality of memory cells based on the first partial data, receiving S150 second partial data, and performing S170 a second program operation on the selected memory cells based on the second partial data. Hereinafter, each operation is described.

For operation S110, the semiconductor memory device 100 may receive first partial data from the memory controller 200. Referring to FIG. 1, the first partial data is program data, and may be data that has been temporarily stored in the buffer memory 215.

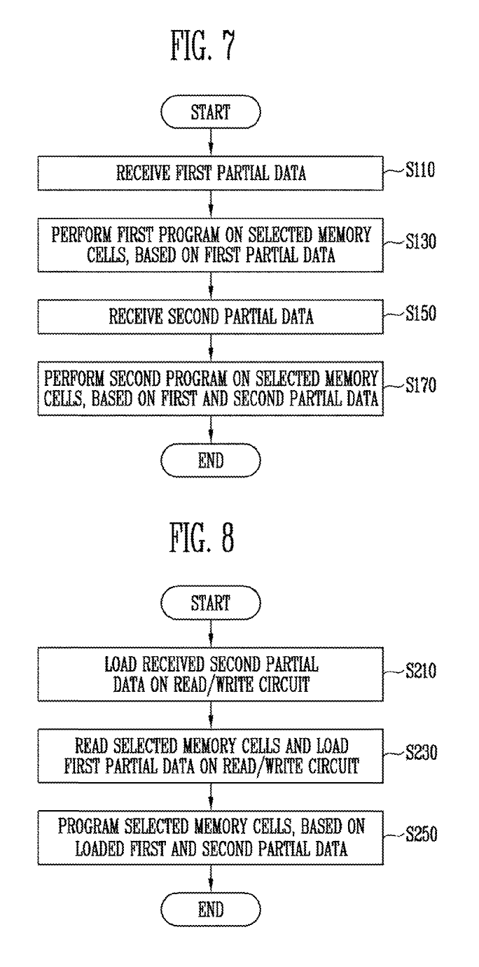

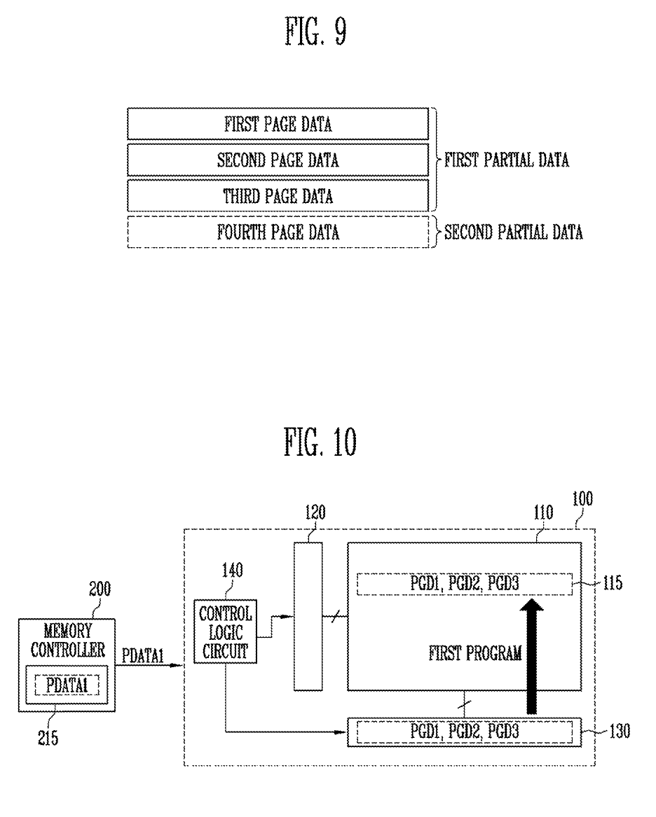

In this specification, “first partial data” and “second partial data” refer to data to be stored in memory cells coupled to a target word line to be selected for a program operation. For example, the first partial data may include at least one piece of logical page data to be stored in each of the memory cells coupled to the target word line. Furthermore, the second partial data may include at least one piece of other logical page data to be stored in each of the memory cells coupled to the target word line. Since the first partial data and the second partial data are programmed to the memory cells coupled to the target word line, each of the memory cells may store at least two or more bits of data. The first partial data and the second partial data are described in detail with reference to FIGS. 9 to 12.

For operation S130, based on the received first partial data, the memory cells coupled to the target word line are programmed. A program operation of operation S130 may be referred to as “first program operation.” During the first program operation, at least some of the memory cells that have been in an erased state are programmed. As the first program operation is completed, each of the memory cells coupled to the target word line may store at least one bit of data. The number of bits of data to be stored in the memory cells when the first program operation is completed may be determined depending on the number of pieces of page data included in the first partial data. For example, if the first partial data includes a piece of logical page data, each of the memory cells coupled to the target word line stores 1-bit data when the first program operation is completed. Alternatively, if the first partial data includes two pieces of logical page data, each of the memory cells coupled to the target word line stores 2-bit data when the first program operation is completed. As a further alternative, if the first partial data includes three pieces of logical page data, each of the memory cells coupled to the target word line stores 3-bit data when the first program operation is completed.

For operation S150, the semiconductor memory device 100 may receive second partial data from the memory controller 200. Similar to the first partial data, the second partial data is program data, and may be data that has been temporarily stored in the buffer memory 215.

For operation S170, based on the first partial data and the second partial data, a second program operation is performed on the selected memory cells. Since operation S130 has been performed, the first partial data is stored in the memory cells coupled to the target word line. Thereafter, as operation S150 is additionally performed, the first partial data and the second partial data are stored in the memory cells coupled to the target word line.

As the second program operation of operation S170 is completed, each of the memory cells coupled to the target word line may store at least two bits of data. The number of bits of data to be stored in the memory cells when the second program operation is completed may be determined depending on the number of pieces of page data included in the first partial data and the second partial data. For example, if the first partial data and the second partial data include a total of two pieces of logical page data, each of the memory cells coupled to the target word line stores 2-bit data when the second program operation is completed. Alternatively, if the first partial data and the second partial data include a total of three pieces of logical page data, each of the memory cells coupled to the target word line stores 3-bit data when the second program operation is completed. As a further alternative, if the first partial data and the second partial data include a total of four pieces of logical page data, each of the memory cells coupled to the target word line stores 4-bit data when the second program operation is completed.

According to the conventional program method, after the entirety of page data to be stored in the memory cells has been received, a program operation is performed in a lump. In such case, if a sudden power-off (SPO) event occurs during the program operation, the entirety of the page data is lost.

For a method of operating the semiconductor memory device 100 in accordance with an embodiment of the present disclosure, the first program operation is performed based on the first partial data, and then the second program operation is performed based on the second partial data. Therefore, if an SPO event occurs after the first program operation (operation S130) has been performed on the selected memory cells, the first partial data is retained, although the second partial data is lost. As a result, the operation reliability of the semiconductor memory device 100 may be enhanced.

Furthermore, in the conventional program method, if there is a need to store a plurality of bits of data in each of the memory cells coupled to the target word line, the buffer memory 215 for temporarily storing the entirety of page data is required. For example, to use each of the memory cells coupled to the target word line as a triple-level cell (TLC), the buffer memory 215 must ensure space capable of storing three pieces of page data during a program operation. To use each of the memory cells coupled to the target word line as a quad-level cell (QLC), the buffer memory 215 must ensure space capable of storing four pieces of page data during a program operation. As the number of bits to be stored in each of the memory cells is increased, the buffer capacity required for programming the memory cells coupled to each word line is also increased.

For the method of operating the semiconductor memory device 100 in accordance with an embodiment of the present disclosure, the first program operation is performed based on the first partial data, and then the second program operation is performed based on the second partial data. Therefore, the buffer memory 215 may need space capable of storing only the first partial data or the second partial data. This makes it possible to more flexibly manage the buffer memory 215 of the memory controller 200. Consequently, the operational flexibility of the storage device 10 may be improved. Hereinafter, an example of storing 4-bit data in each of the memory cells coupled to the target word line through a program operation using the first partial data and the second partial data is described. In other words, a QLC program operation is described.

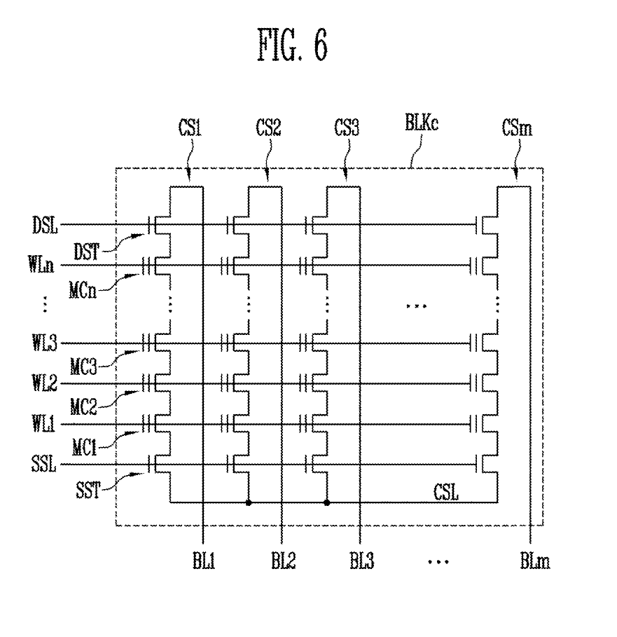

FIG. 8 shows a flowchart illustrating an example of the program operation S130 of FIG. 7. FIG. 9 shows a diagram illustrating first partial data and second partial data, in accordance with an embodiment of the present disclosure. Below, an embodiment of the present disclosure is described with reference to FIGS. 8 and 9.

Referring to FIG. 9, there are illustrated four pieces of page data to be stored in memory cells (e.g., QLCs) coupled to a target word line. Because the first to fourth page data are stored in the memory cells coupled to the single target word line, each memory cell may store 4-bit data. Furthermore, in the embodiment of FIG. 9, the first partial data includes the first to third page data, and the second partial data includes the fourth page data. Hence, after operation S130 of FIG. 7 has been performed, 3-bit data may be stored in each of the memory cells.

At operation S150 of FIG. 7, the fourth page data, which is the second partial data, may be received by the semiconductor memory device 100 from the memory controller 200. For an embodiment, to additionally store the fourth page data in each of the memory cells in which the 3-bit data has already been stored, the read/write circuit needs not only the fourth page data but also the first to third page data. If the first program operation of step S130 is completed, each of the page buffers PB1 to PBm included in the read/write circuit 130 no longer retains the first partial data. Therefore, to perform operation S170 of FIG. 7, not only the second partial data but also the first partial data is be applied to the read/write circuit 130.

Referring to FIG. 8, after the fourth page data, which is the second partial data, has been received by the semiconductor memory device 100 from the memory controller 200, the received second partial data is loaded on the read/write circuit 130. In other words, the fourth page data may be stored in data latches included in the respective page buffers PB1 to PBm of the read/write circuit 130. Hence, each of the page buffers of the read/write circuit 130 stores 1-bit data included in the fourth page data.

For operation S230, a read operation is performed on the memory cells coupled to the target word line. Because the first to third page data, which is the first partial data, has been stored in the memory cells, the first partial data may be loaded on the read/write circuit 130. In other words, the first to third page data may be stored in the data latches included in the respective page buffers PB1 to PBm of the read/write circuit 130. Hence, each of the page buffers PB1 to PBm of the read/write circuit 130 additionally stores 3-bit data included in the first to third page data. As a result, after operation S230 has been performed, each of the page buffers PB1 to PBm of the read/write circuit 130 stores 4-bit data included in the first to third page data.

For operation S250, based on the first and the second partial data loaded on the read/write circuit 130, the memory cells coupled to the target word line are programmed. Because all of the first to fourth page data have been stored in the page buffers of the read/write circuit 130, 4-bit data is stored in each of the selected memory cells as operation S250 is performed.

For an embodiment in accordance with FIG. 8, after the first partial data has been programmed, the memory controller 200 may remove the first partial data from the buffer memory 215. Thereafter, to program the second partial data, the memory controller 200 may retain just the second partial data in the buffer memory 215 and not the first partial data. The semiconductor memory device 100 receives the second partial data and reads the first partial data from the memory cells that have been already programmed. Therefore, although the buffer memory 215 of the memory controller 200 does not retain the first partial data, the second program operation may be performed based on the first partial data and the second partial data. Therefore, the available capacity of the buffer memory 215 is effectively increased, thus making it possible to more flexibly manage the buffer memory 215 of the memory controller 200. As a result, the operational flexibility of the storage device 10 may be enhanced.

In FIG. 9, there is illustrated the case where the first partial data includes three pieces of page data, and the second partial data includes one piece of page data. However, this is only for illustrative purposes. For example, the first partial data may include two pieces of page data, and the second partial data may also include two pieces of page data. Alternatively, the first partial data may include one piece of page data, and the second partial data may include three pieces of page data.

In FIG. 9, there is illustrated the case where a total of four pieces of page data are programmed during the first and the second program operations. In other words, for an embodiment in accordance with FIG. 9, each of the memory cells acts as a QLC capable of storing 4-bit data. However, this is only for illustrative purposes. For example, each of the memory cells may act as a TLC capable of storing 3-bit data. In such case, during the first and the second program operations, a total of three pieces of page data may be programmed to the memory cells coupled to the single target word line. Alternatively, each of the memory cells may be configured to store five or more bits of data. In this case, during the first and the second program operations, a total of five pieces of page data may be programmed to the memory cells coupled to the single target word line.

Hereinafter, the method of operating the semiconductor memory device shown in FIGS. 7 and 8 is described in more detail with reference to FIGS. 10 to 14.

FIGS. 10, 11, and 12 show block diagrams for explaining the method of operating the semiconductor memory device 100 in accordance with an embodiment relating to FIG. 8.

Referring to FIG. 10, the memory controller 200 and the semiconductor memory device 100 are illustrated. The memory controller 200 includes a buffer memory 215. Furthermore, the semiconductor memory device 100 includes a memory cell array 110, a address decoder 120, a read/write circuit 130, and a control logic circuit 140. The memory cell array 110 includes a plurality of memory cells. Memory cells 115 coupled to a target word line selected as a target to be programmed are included in the plurality of memory cells.

For the sake of illustration, components not needed to describe an embodiment of the present disclosure are omitted.

FIG. 10 illustrates the operations S110 and S130 of FIG. 7. To perform a first program operation, the buffer memory 215 of the memory controller 200 stores first partial data PDATA1. As described with reference to FIG. 9, the first partial data PDATA1 includes first to third page data PGD1, PGD2, and PGD3. The semiconductor memory device 100 receives the first partial data PDATA1 from the memory controller 200. The first to third page data PGD1, PGD2, and PGD3 included in the first partial data PDATA1 are loaded on the read/write circuit 130. The control logic circuit 140 may control the address decoder 120 and the read/write circuit 130 to program the loaded first to third page data PGD1, PGD2, and PGD3 to the selected memory cells 115. During the first program operation, the first partial data PDATA1 is programmed to the selected memory cells 115. After the first program operation has been completed, the first partial data PDATA1 that has been stored in the buffer memory 215 of the memory controller 200 may be removed.

FIG. 11 illustrates operations S210 and S230 of FIG. 8. To perform a second program operation, the buffer memory 215 of the memory controller 200 stores second partial data PDATA2. As described with reference to FIG. 9, the second partial data PDATA2 includes fourth page data PGD4. The semiconductor memory device 100 receives the second partial data PDATA2 from the memory controller 200. The fourth page data PGD4 included in the second partial data PDATA2 is loaded on the read/write circuit 130.

To perform the second program operation, the semiconductor memory device 100 performs a data read operation on the selected memory cells 115. Thereby, the first partial data PDATA1, i.e., the first to third page data PGD1, PGD2, and PGD3, stored in the selected memory cells 115 is loaded on the read/write circuit 130. Consequently, all of the first to fourth page data PGD1, PGD2, PGD3, and PGD4 are loaded on the read/write circuit 130.

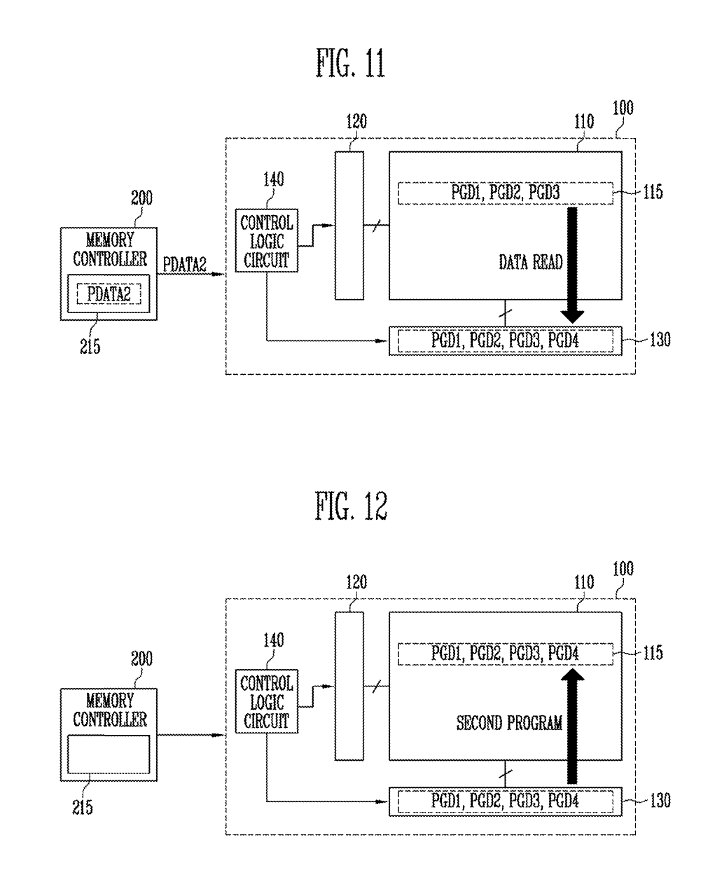

FIG. 12 illustrates the operation S250 of FIG. 8. The control logic circuit 140 performs the second program operation on the selected memory cells 115, based on the first to fourth page data PGD1, PGD2, PGD3, and PGD4 loaded on the read/write circuit 130. If the second program operation is completed, then both the first and the second partial data PDATA1 and PDATA2 are stored in the selected memory cells.

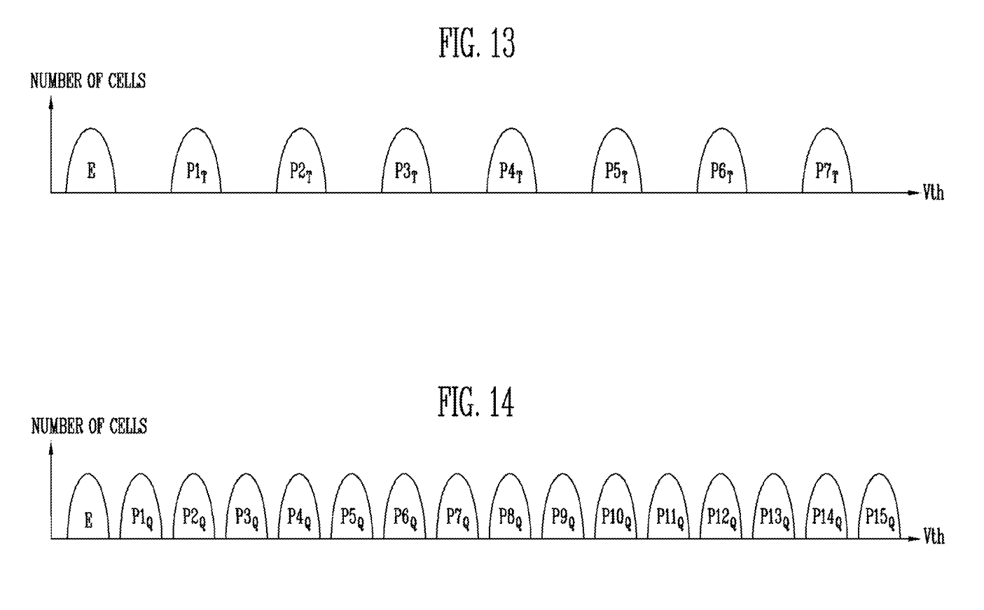

FIGS. 13 and 14 show diagrams illustrating threshold voltage distributions of memory cells as a result of the first program operation and the second program operation, in accordance with an embodiment of the present disclosure.

FIG. 13 illustrates the threshold voltage distributions of the selected memory cells 115 as a result of the first program operation described with reference to FIG. 10. During the first program operation, the first to third page data PGD1, PGD2, and PGD3 are programmed to the memory cells 115. This process may be performed in substantially the same manner as an operation of programming a TLC. As a result, each of the memory cells 115 is programmed to any one state of an erased state E and first to seventh programmed states P1_{T}, P2_{T}, P3_{T}, P4_{T}, P5_{T}, P6_{T}, and P7_{T}.

Referring to FIG. 14, the memory cells 115 having the threshold voltage distributions of FIG. 13 are secondarily programmed to sixteen programmed states during the second program operation. For example, during the second program operation, each of the memory cells that were in the erased state E of FIG. 13 may have any one state of an erase state E and a first programmed state P1_{Q} of FIG. 14. Furthermore, during the second program operation, each of the memory cells that were in the first programmed state P1_{T} of FIG. 13 may have any one state of a second programmed state P2_{Q} and a third programmed state P3_{Q} of FIG. 14. Furthermore, during the second program operation, each of the memory cells that were in the second programmed state P2_{T} of FIG. 13 may have any one state of a fourth programmed state P4_{Q} and a fifth programmed state P5_{Q} of FIG. 14. Furthermore, during the second program operation, each of the memory cells that were in the third programmed state P3_{T} of FIG. 13 may have any one state of a sixth programmed state P6_{Q} and a seventh programmed state P7_{Q} of FIG. 14. Furthermore, during the second program operation, each of the memory cells that were in the fourth programmed state P4_{T} of FIG. 13 may have any one state of an eighth programmed state P8_{Q} and a ninth programmed state P9_{Q} of FIG. 14. Furthermore, during the second program operation, each of the memory cells that were in the fifth programmed state P5_{T} of FIG. 13 may have any one state of a tenth programmed state P10_{Q} and a eleventh programmed state P11_{Q} of FIG. 14. Furthermore, during the second program operation, each of the memory cells that were in the sixth programmed state P6_{T} of FIG. 13 may have any one state of a twelfth programmed state P12_{Q} and a thirteenth programmed state P13_{Q} of FIG. 14. Lastly, during the second program operation, each of the memory cells that were in the seventh programmed state P7_{T} of FIG. 13 may have any one state of a fourteenth programmed state P14_{Q} and a fifteenth programmed state P15_{Q} of FIG. 14.

As described above, if the supply of power to the semiconductor memory device 100 is suddenly interrupted during the second program operation, after the first program operation has been performed, the second partial data PDATA2 is lost. However, in such case, as shown in FIG. 13, the first to third page data PGD1, PGD2, and PGD3, which are the first partial data PDATA1, may be retained. Consequently, the operational reliability of the semiconductor memory device 100 is enhanced.

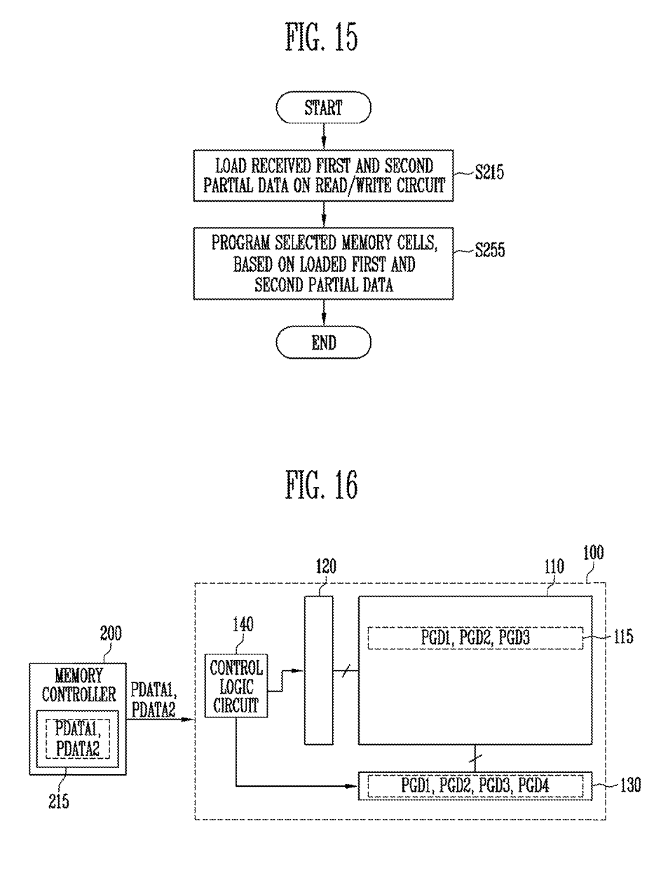

FIG. 15 shows a flowchart illustrating an example of the second program operation S170 of FIG. 7. FIG. 16 shows a block diagram for explaining a method of operating the semiconductor memory device 100 in accordance with FIG. 15. Hereinafter, an example of the second program step S170 is described with reference to FIGS. 15 and 16.

FIGS. 8 and 11 illustrate the first partial data PDATA1 being loaded on the read/write circuit 130 during the operation of reading the selected memory cell 115. For FIG. 15, the first partial data PDATA1 is received from the memory controller 200. In other words, for operation S150 of FIG. 7, not only the second partial data PDATA2 but also the first partial data PDATA1 is received from the memory controller 200.

For operation S215 of FIG. 15, the received first and second partial data PDATA1 and PDATA2 are loaded on the read/write circuit 130. Thereafter, for operation S255, based on the loaded first and second partial data PDATA1 and PDATA2, the selected memory cells are programmed. In the embodiment of FIG. 8, the first partial data PDATA1 needed for the second program operation is read from the memory cells and then loaded on the read/write circuit 130. On the other hand, in the embodiment of FIG. 15, the first partial data PDATA1 along with the second partial data PDATA2 is received from the memory controller 200 and then loaded on the read/write circuit 130.

Below, descriptions are presented with reference to the drawings in a sequence of FIGS. 10, 16, and 12. As described above with reference to FIG. 10, the first partial data PDATA1 is transmitted to the semiconductor memory device 100 so that the first to third page data PGD1, PGD2, and PGD3 are programmed to the memory cells 115. Thereafter, as shown in FIG. 16, the first and second partial data PDATA1 and PDATA2 that have been stored in the buffer memory 215 of the memory controller 200 are transmitted to the semiconductor memory device 100. The semiconductor memory device 100 loads the received first and second partial data PDATA1 and PDATA2 on the read/write circuit 130 without performing a read operation. Thereby, the first to fourth page data PGD1, PGD2, PGD3, and PGD4 may be stored in the data latches included in the respective page buffers PB1 to PBm of the read/write circuit 130. Subsequently, as shown in FIG. 12, based on the first and second partial data PDATA1 and PDATA2 loaded on the read/write circuit 130, a second program operation may be performed on the memory cells 115.

In other words, depending on conditions of the buffer memory 215, the memory controller 200 may retain the first partial data PDATA1 after the first program operation, or may erase the first partial data PDATA1 from the buffer memory 215. In the case where the first partial data PDATA1 is erased so as to ensure the capacity of the buffer memory 215, the memory controller 200 may transmit just the second partial data PDATA2 to the semiconductor memory device 100 during the second program operation. In this case, as shown in FIGS. 8 and 11, the first partial data PDATA1 is read from the memory cells 115 and loaded on the read/write circuit 130.

If the buffer memory 215 has spare storage space, and thus retains the first partial data PDATA1 until the second program operation, the memory controller 200 transmits the first partial data PDATA1 along with the second partial data PDATA2 to the semiconductor memory device 100. In this case, the entire program speed may be increased because the operation of reading the first partial data PDATA1 from the memory cells 115 is omitted.

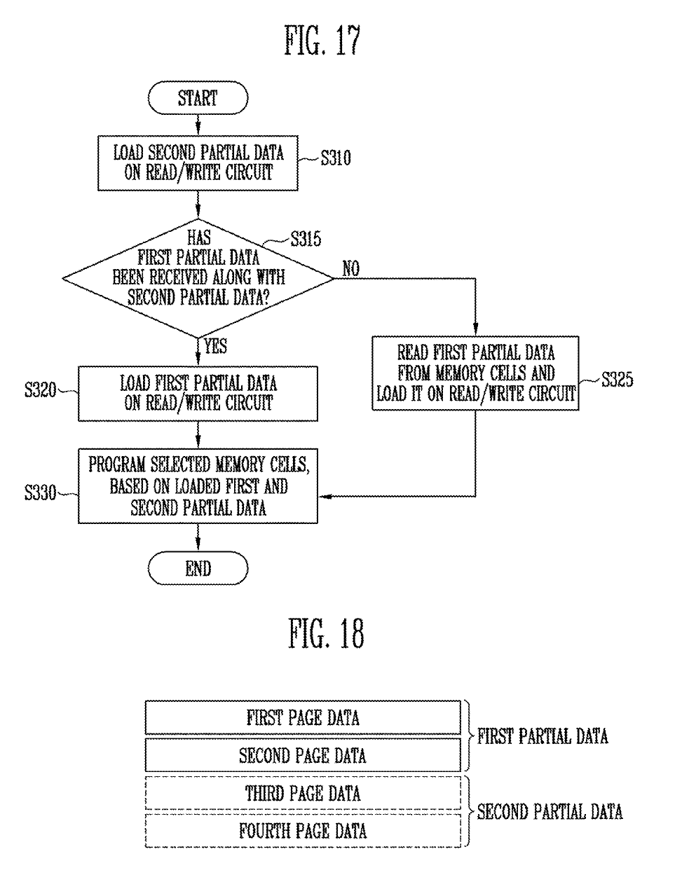

FIG. 17 shows a flowchart illustrating a method of operating the semiconductor memory device, in accordance with an embodiment of the present disclosure. Referring to FIG. 17, there is illustrated a method obtained by combining the embodiments of FIGS. 8 and 15. FIG. 17 illustrates subdivided operations of operation S170 described with reference to FIG. 7.

After the first program operation has been completed for operations S110 and S130 of FIG. 7, the semiconductor memory device 100 may receive the second partial data PDATA2 from the memory controller 200 (operation S150). Thereafter, for operation S310 of FIG. 17, the received second partial data PDATA2 is loaded on the read/write circuit 130. For operation S315, it is determined whether the first partial data PDATA1 along with the second partial data PDATA2 has been received. If the first partial data PDATA1 along with the second partial data PDATA2 is received, there is no need to perform a data read operation. Therefore, the process proceeds to operation S320, so that the received first partial data PDATA1 is loaded on the read/write circuit 320. Thereafter, based on the loaded first and second partial data PDATA1 and PDATA2, the selected memory cells 115 are programmed.

If, as the result of the determination of operation S315, the first partial data PDATA1 has not been received from the memory controller 200, the process proceeds to operation S325 to read the first partial data PDATA1 from the memory cells 115. The read first partial data PDATA1 may be loaded on the read/write circuit 130. Thereafter, the process proceeds to operation S330, the selected memory cells 115 are programmed based on the loaded first and second partial data PDATA1 and PDATA2.

FIG. 18 shows a diagram illustrating first partial data and second partial data, in accordance with an embodiment of the present disclosure. Referring to FIG. 18, there are illustrated four pieces of page data to be stored in memory cells (e.g., QLCs) coupled to a target word line. Because first to fourth page data are stored in the memory cells coupled to the single target word line, each memory cell may store 4-bit data. According to the embodiment of FIG. 9 described above, the first partial data includes the first to third page data, and the second partial data includes the fourth page data. According to the embodiment of FIG. 18, the first partial data includes the first and the second page data, and the second partial data includes the third and the fourth page data.

Hence, after operation S130 of FIG. 7 has been performed, 2-bit data may be stored in each of the memory cells. After operation S170 of FIG. 7 has been performed, 4-bit data may be stored in each of the memory cells.

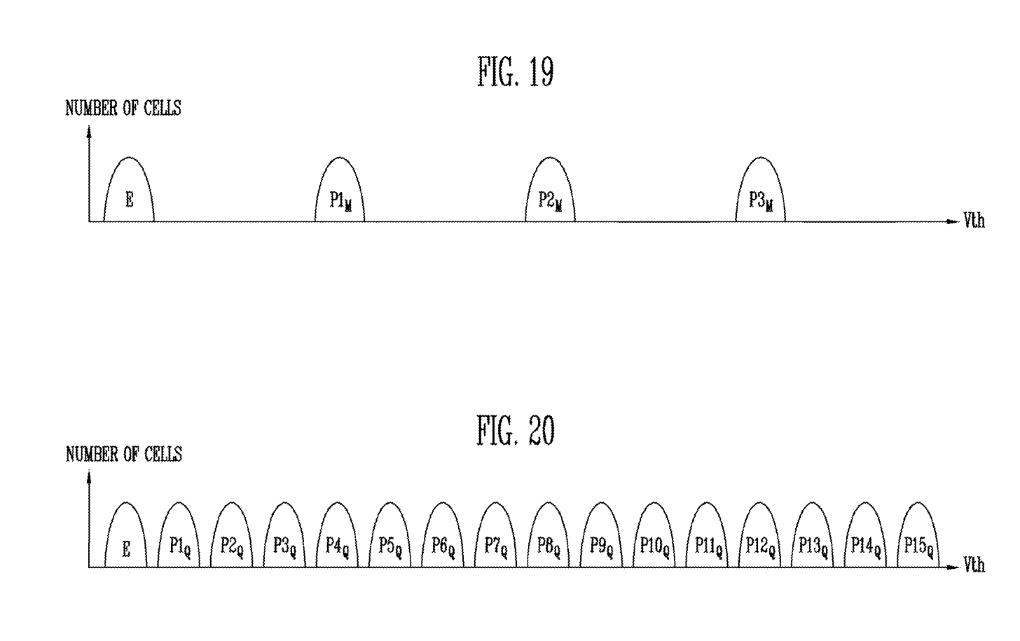

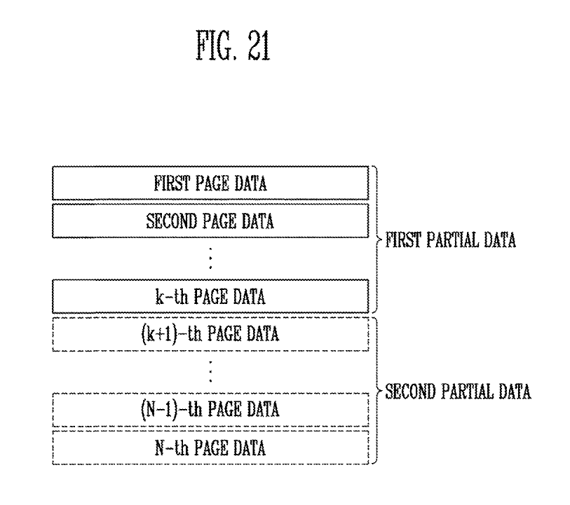

FIGS. 19 and 20 show diagrams illustrating threshold voltage distributions of memory cells as a result of the first program operation and the second program operation, in accordance with an embodiment of the present disclosure.

FIG. 19 illustrates the threshold voltage distributions of the selected memory cells 115 as a result of the first program operation performed according to the embodiment of FIG. 18. During the first program operation, the first and the second page data are programmed to the memory cells 115. This process may be performed in substantially the same manner as that of an operation of programming an MLC. As a result, each of the memory cells 115 is programmed to any one state of an erased state E and first to third programmed states P1_{M}, P2_{M}, and P3_{M}.

Referring to FIG. 20, the memory cells 115 having the threshold voltage distributions of FIG. 19 are secondarily programmed to sixteen programmed states during the second program operation. For example, during the second program operation, each of the memory cells that were in the erased state E of FIG. 19 may have any one state of an erase state E and first to third programmed states P1_{Q} to P3_{Q} of FIG. 20. Furthermore, during the second program operation, each of the memory cells that were in the first programmed state P1_{M} of FIG. 19 may have any one state of fourth to seventh programmed states P4_{Q} to P7_{Q} of FIG. 20. Furthermore, during the second program operation, each of the memory cells that were in the second programmed state P2_{M} of FIG. 19 may have any one state of eighth to eleventh programmed states P8_{Q} to P11_{Q} of FIG. 20. Lastly, during the second program operation, each of the memory cells that were in the third programmed state P3_{M} of FIG. 19 may have any one state of twelfth to fifteenth programmed states P12_{Q} to P15_{Q} of FIG. 20.

As described above, if the supply of power to the semiconductor memory device 100 is suddenly interrupted during the second program operation, after the first program operation has been performed, the second partial data PDATA2 is lost. However, in such case, as shown in FIG. 19, the first and second page data PGD1 and PGD2, which are the first partial data PDATA1, may be retained. Consequently, the operational reliability of the semiconductor memory device 100 is enhanced.

FIGS. 9 and 18 represent a limited number of embodiments. Various other embodiments are also possible. For example, in an embodiment, the first partial data may include first page data, and the second partial data may include second to fourth page data.

In the above-mentioned embodiments, during the first and the second program operations, each of the memory cells is operated as a QLC capable of storing 4-bit data. However, the semiconductor memory device and the method of operating the semiconductor memory device in accordance with embodiments of the present disclosure are not limited to the foregoing example.

For example, during the first and the second program operations, each of the memory cells may be operated as a TLC capable of storing 3-bit data. In this case, in an embodiment, first partial data to be programmed during the first program operation may include first and second page data, and second partial data to be programmed during the second program operation may include third page data. In an embodiment, first partial data to be programmed during the first program operation may include first page data, and second partial data to be programmed during the second program operation may include second and third page data.

Alternatively, the semiconductor memory device may be configured such that, during the first and the second program operations, each of the memory cells stores five or more bits of data. In this case, it is to be understood that various combinations of first and second partial data may be formed.

FIG. 21 shows a diagram illustrating first and second partial data in data formed of N pages, in accordance with an embodiment of the present disclosure.

Referring to FIG. 21, there are illustrated N pieces of page data to be stored in memory cells coupled to a target word line. Here, N is a natural number of 2 or more. Because first to N-th page data are stored in the memory cells coupled to the single target word line, each memory cell may store N-bit data. Hence, if data is stored in the memory cells coupled to the target word line, each of the memory cells may be programmed to any one state of an erased state E and first to 2N−1-th programmed states.

Furthermore, in the embodiment of FIG. 21, the first partial data includes first to k-th page data, and the second partial data includes k+1-th to N-th page data. Here, k may be a natural number of 1 or more and less than N. The expressions “k+1-th” and “N-th” include a hyphen, rather than a minus sign, and mean (k+1)^{th} and N^{th}, respectively.

Hence, after operation S130 of FIG. 7 has been performed, k-bit data may be stored in each of the memory cells. After operation S170 of FIG. 7 has been performed, N-bit data may be stored in each of the memory cells.

Referring to FIGS. 9 to 20, there are illustrated embodiments in which a total of four page data are programmed during the first and the second program operations. In other words, for the embodiments of FIGS. 9 to 20, each of the memory cells acts as a QLC capable of storing 4-bit data. However, this is only for illustrative purposes, and, as shown FIG. 21, each of the memory cells may be operated as a memory cell capable of storing N-bit data. In this case, during the first and the second program operations, a total of N pieces of page data may be programmed to the memory cells coupled to the single target word line.

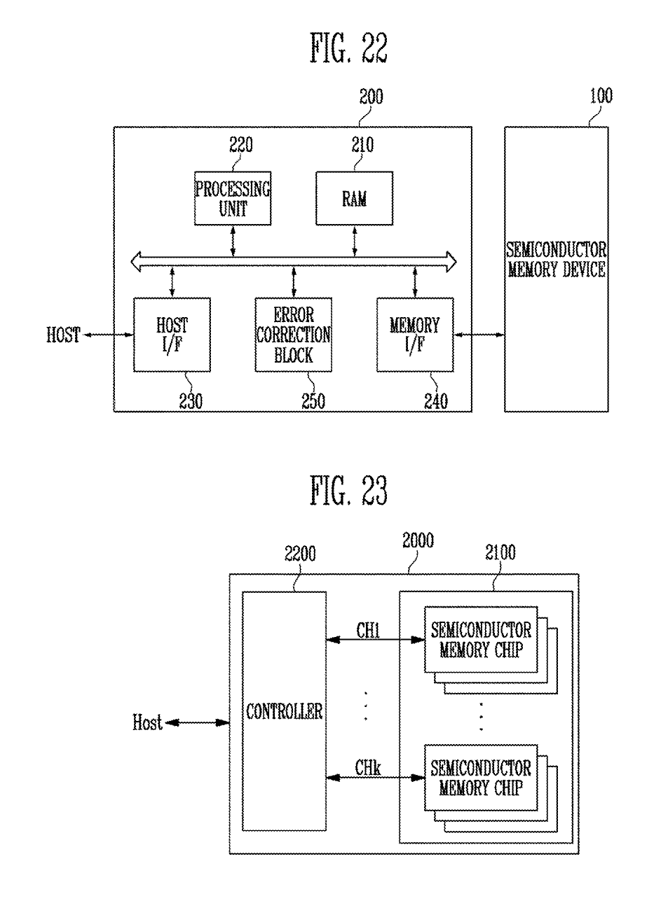

FIG. 22 shows a block diagram illustrating an example of the memory controller 200 shown in FIG. 1.

Referring to FIG. 22, the memory controller 200 is coupled with a semiconductor memory device 100 and a host HOST. The semiconductor memory device 100 may be the semiconductor memory device described with reference to FIG. 2. The memory controller 200 corresponds to the memory controller 200 of FIG. 1. Hereinafter, repetitive explanations are omitted.

The memory controller 200 may access the semiconductor memory device 100 in response to a request from the host HOST. For example, the memory controller 200 may control a read operation, a write operation, an erase operation, and a background operation of the semiconductor memory device 100. The memory controller 200 may provide an interface between the host HOST and the semiconductor memory device 100. The memory controller 200 may drive firmware for controlling the semiconductor memory device 100.

The memory controller 200 may include a random access memory (RAM) 210, a processing unit 220, a host interface 230, a memory interface 240, and an error correction block 250. The RAM 210 may be used as at least one of an operating memory for the processing unit 220, a cache memory between the semiconductor memory device 100 and the host HOST, and a buffer memory between the semiconductor memory device 100 and the host HOST. For example, at least a portion of the buffer memory 215 of FIG. 1 may be formed as a portion of the RAM 210 of FIG. 22.

The processing unit 220 may control the overall operation of the memory controller 200.

The host interface 230 may include a protocol for performing data exchange between the host HOST and the controller 200. In an embodiment, the memory controller 200 may communicate with the host HOST through at least one of various interface protocols, such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, and a private protocol.

The memory interface 240 may interface with the semiconductor memory device 100. For example, the memory interface may include a NAND interface or a NOR interface.

The error correction block 250 may use an error correcting code (ECC) to detect and correct an error in data received from the semiconductor memory device 100. The processing unit 220 may control the semiconductor memory device 100 to adjust the read voltage according to an error detection result from the error correction block 250 and perform re-reading. In an embodiment, the error correction block 250 may be provided as a component of the memory controller 200.

The memory controller 200 and the semiconductor memory device 100 may be integrated into a single semiconductor device. In an embodiment, the memory controller 200 and the semiconductor memory device 100 may be integrated into a single semiconductor device to form a memory card. For example, the memory controller 200 and the semiconductor memory device 100 may be integrated into a single semiconductor device and form a memory card such as a personal computer memory card international association (PCMCIA), a compact flash card (CF), a smart media card (SM or SMC), a memory stick multimedia card (MMC, RS-MMC, or MMCmicro), a SD card (SD, miniSD, microSD, or SDHC), and a universal flash storage (UFS).

The memory controller 200 and the semiconductor memory device 100 may be integrated into a single semiconductor device to form a solid state drive (SSD). The SSD may include a storage device configured to store data to a semiconductor memory. When the storage device including the memory controller 200 and the semiconductor memory device 100 is used as the SSD, the operating speed of the host HOST coupled to the storage device can be greatly improved.

In an embodiment, the storage device including the memory controller 200 and the semiconductor memory device 100 may be provided as one of various elements of an electronic device, such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various elements for forming a computing system, or the like.

In an embodiment, the semiconductor memory device 100 and the storage device including the semiconductor memory device 100 may be embedded in various types of packages. For example, the semiconductor memory device 100 or the storage device may be packaged in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), or Wafer-Level Processed Stack Package (WSP).

FIG. 23 shows a block diagram illustrating an application example of the storage device 2000, which for an embodiment, represents the storage device 10 of FIG. 1.

Referring FIG. 23, the storage device 2000 includes a semiconductor memory device 2100 and a controller 2200. The semiconductor memory device 2100 may include a plurality of semiconductor memory chips. The semiconductor memory chips are divided into a plurality of groups.

As illustrated, the respective groups communicate with the controller 2200 through first to k-th channels CH1 to CHk. Each semiconductor memory chip may be configured and operated in the same manner as those of the semiconductor memory device 100 described with reference to FIG. 2.

Each group may communicate with the controller 2200 through one common channel. The controller 2200 may have the same configuration as that of the memory controller 200 described with reference to FIG. 22 and control a plurality of memory chips of the semiconductor memory device 2100 through the plurality of channels CH1 to CHk.

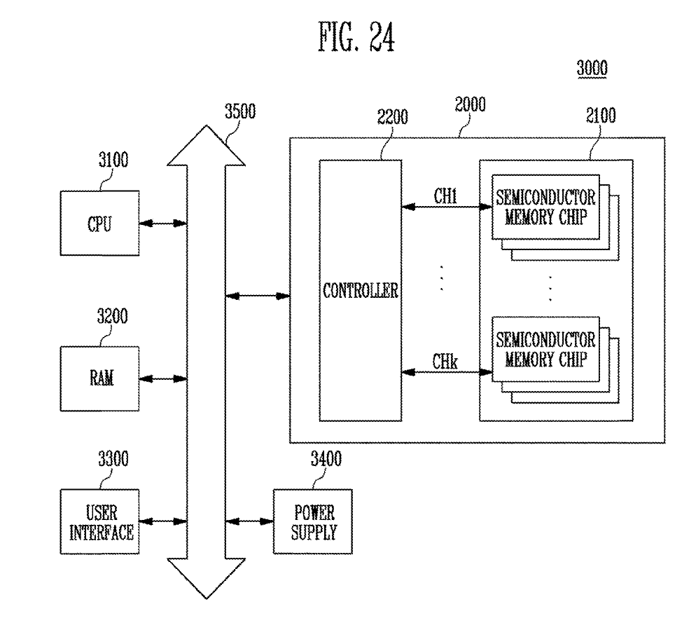

FIG. 24 shows a block diagram illustrating a computing system 3000 including the storage device 2000 described with reference to FIG. 23.

The computing system 3000 may include a central processing unit (CPU) 3100, a RAM 3200, a user interface 3300, a power supply 3400, a system bus 3500, and the storage device 2000.

The storage device 2000 may be electrically coupled to the CPU 3100, the RAM 3200, the user interface 3300, and the power supply 3400 through the system bus 3500. Data provided through the user interface 3300 or processed by the CPU 3100 may be stored in the storage device 2000.

In FIG. 24, the semiconductor memory device 2100 has been illustrated as being coupled to the system bus 3500 through the controller 2200. Alternatively, the semiconductor memory device 2100 may be directly coupled to the system bus 3500. The function of the controller 2200 may be performed by the CPU 3100 and the RAM 3200.

Referring to FIG. 24, the storage device 2000, described with reference to FIG. 23, may be provided. However, the storage device 2000 may be replaced with the storage device including the memory controller 200 and the semiconductor memory device 100 that has been described with reference to FIG. 22.

Various embodiments of the present disclosure may provide a semiconductor memory device having enhanced operational performance.

Various embodiments of the present disclosure may provide a method of operating a semiconductor memory device having enhanced operational performance.

Examples of embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments, unless otherwise specifically indicated. Accordingly, it will be understood by those of skill in the art that various changes in form and details may be made without departing from the spirit and scope of the present disclosure as set forth in the following claims.

What is claimed is:

1. A semiconductor memory device comprising:
a memory cell array comprising a plurality of memory cells, each memory cell of which is configured to store a plurality of bits of data;
a peripheral circuit configured to drive the memory cell array; and
a control logic circuit configured to control the peripheral circuit to perform a first program operation on target memory cells of the plurality of memory cells based on first partial data, and to perform a second program operation on the target memory cells based on second partial data received after the first program operation is completed, wherein the target memory cells are coupled to a target word line.

2. The semiconductor memory device according to claim 1,
wherein the first partial data includes first page data, second page data, and third page data, and
wherein, after the first program operation is completed, 3-bit data is stored in each of the target memory cells.

3. The semiconductor memory device according to claim 2,
wherein the second partial data includes fourth page data, and
wherein, after the second program operation is completed, 4-bit data is stored in each of the target memory cells.

4. The semiconductor memory device according to claim 1,
wherein the first partial data includes first page data and second page data, and
wherein, after the first program operation is completed, 2-bit data is stored in each of the target memory cells.

5. The semiconductor memory device according to claim 4,
wherein the second partial data includes third page data and fourth page data, and
wherein, after the second program operation is completed, 4-bit data is stored in each of the target memory cells.

6. The semiconductor memory device according to claim 4,
wherein the second partial data includes third page data, and
wherein, after the second program operation is completed, 3-bit data is stored in each of the target memory.

7. The semiconductor memory device according to claim 1, wherein the control logic circuit controls the peripheral circuit to read the first partial data stored in the target memory cells and to perform the second program operation based on the read first partial data and the received second partial data.

8. The semiconductor memory device according to claim 1,
wherein after the first program operation, the first partial data and the second partial data are received, and
wherein the control logic circuit controls the peripheral circuit to perform the second program operation based on the received first partial data and the received second partial data.

9. The semiconductor memory device according to claim 1,
wherein the peripheral circuit comprises a read/write circuit coupled to the memory cell array through a plurality of bit lines,
wherein, during the first program operation, the first partial data is loaded on the read/write circuit, and
wherein, during the second program operation, the first partial data and the second partial data are loaded on the read/write circuit.

10. A method of operating a semiconductor memory device including a plurality of memory cells, the method comprising:
receiving first partial data;
performing a first program operation on selected memory cells of the plurality of memory cells based on the first partial data;
receiving second partial data; and
performing a second program operation on the selected memory cells based on the first partial data and the second partial data.

11. The method according to claim 10, wherein performing the second program operation comprises:
loading the second partial data on a read/write circuit coupled to the selected memory cells;
reading the selected memory cells and loading the first partial data on the read/write circuit; and
programming the selected memory cells based on the loaded first and second partial data.

12. The method according to claim 10,
wherein, in receiving the second partial data, the first partial data is received along with the second partial data, and
wherein performing the second program operation comprises:
loading the first partial data and the second partial data on a read/write circuit coupled to the selected memory cells; and
programming the selected memory cells based on the loaded first and second partial data.

13. The method according to claim 10, wherein performing the second program operation comprises:
loading the second partial data on a read/write circuit coupled to the selected memory cells;
determining whether the first partial data has been received along with the second partial data;
loading the first partial data on the read/write circuit based on a result of the determining; and
programming the selected memory cells based on the loaded first partial data and the loaded second partial data.

14. The method according to claim 13, wherein the loading of the first partial data on the read/write circuit based on the result of the determining comprises loading, when the first partial data is received along with the second partial data, the received first partial data on the read/write circuit.

15. The method according to claim 13, wherein the loading of the first partial data on the read/write circuit based on the result of the determining comprises reading, when the first partial data is not received along with the second partial data, the first partial data from the selected memory cells and loading the first partial data on the read/write circuit.

16. The method according to claim 10, wherein, when performing the first program operation is completed, 3-bit data is stored in each of the selected memory cells.

17. The method according to claim 16, wherein, when performing the second program operation is completed, 4-bit data is stored in each of the selected memory cells.

18. The method according to claim 10, wherein, when performing the first program operation is completed, 2-bit data is stored in each of the selected memory cells.

19. The method according to claim 18, wherein, when performing the second program operation is completed, 2-bit data is stored in each of the selected memory cells.

20. A method of operating a semiconductor memory device to program N pages of data to a plurality of memory cells coupled to a target word line, wherein N is a natural number of at least 2, the method comprising:
receiving first partial data including first to k-th page data, wherein k is a natural number of at least 1 and less than N;
performing a first program operation on the plurality of memory cells coupled to the target word line based on the first partial data;
receiving second partial data comprising (k+1)-th to N-th page data; and
performing a second program operation on the plurality of memory cells coupled to the target word line based on the first partial data and the second partial data.
